(19) United States
(12) Patent Application Publication
(10) Pub. No.: US 2025/0013157 A1
(43) Pub. Date: Jan. 9, 2025

(54) MANUFACTURING METHOD OF OVERLAY MARK AND OVERLAY MEASUREMENT METHOD

(71) Applicant: United Microelectronics Corp., Hsinchu (TW)

(72) Inventors: Chun-Yi Chang, Taichung City (TW); Chien-Hao Chen, Tainan City (TW)

(73) Assignee: United Microelectronics Corp., Hsinchu (TW)

(21) Appl. No.: 18/447,324

(22) Filed: Aug. 10, 2023

(30) Foreign Application Priority Data
Jul. 4, 2023 (CN) 202310811871.0

(51) Int. Cl. G03F 7/00

(52) U.S. Cl. CPC G03F 7/70633

(57) ABSTRACT

Provided are a manufacturing method of an overlay mark and an overlay measurement method. The manufacturing method includes the following steps. A first stitching overlay mark structure having a plurality of first patterns is formed on a first layer. A second layer is formed on the first layer. A second stitching overlay mark structure having a plurality of second patterns is formed on the second layer. The second stitching overlay mark structure is located above the first stitching overlay mark structure, and from the top view on the second layer, the second patterns and the first patterns are alternately arranged.

### CROSS-REFERENCE TO RELATED APPLICATION

This application claims the priority benefit of China application serial no. 202310811871.0, filed on Jul. 4, 2023. The entirety of the above-mentioned patent application is hereby incorporated by reference herein and made a part of this specification.

### BACKGROUND

### Technical Field

The present invention relates to a manufacturing method of a mark for a semiconductor process and an application of the mark, and in particular to a manufacturing method of an overlay mark and an overlay measurement method.

### Description of Related Art

In the semiconductor process, the overlay mark may be used to check the alignment between a pattern and another pattern. For example, the stitching overlay mark may be used to check the stitching alignment between the target patterns in the same layer, and the layer-to-layer overlay mark may be used to check the layer-to-layer alignment between the target patterns in different layers.

The stitching overlay mark and the layer-to-layer overlay mark are usually disposed in different regions of a chip respectively, and thus more layout area is occupied. In addition, for the stitching overlay measurement and the layer-to-layer overlay measurement, different overlay marks located in different regions need to be used, so the measurement step is more complicated.

### SUMMARY

The present invention provides a manufacturing method of an overlay mark, in which the stitching overlay mark structures are formed in different layers respectively, and the stitching overlay mark structures in different layers are disposed in a layer-to-layer overlay mark structure.

The present invention provides an overlay measurement method, in which the phase shift measurement is used to perform overlay measurement on the above-mentioned overlay mark.

The manufacturing method of the overlay mark of the present invention includes the following steps. A first stitching overlay mark structure having a plurality of first patterns is formed on a first layer. A second layer is formed on the first layer. A second stitching overlay mark structure having a plurality of second patterns is formed on the second layer. The second stitching overlay mark structure is located above the first stitching overlay mark structure, and from the top view on the second layer, the second patterns and the first patterns are alternately arranged.

In an embodiment of the manufacturing method of the overlay mark of the present invention, the plurality of first patterns includes a plurality of first sub-patterns and a plurality of second sub-patterns arranged alternately.

In an embodiment of the manufacturing method of the overlay mark of the present invention, a forming method of the first stitching overlay mark structure includes the following steps. The first sub-patterns are formed on the first layer using patterns at a first side of a first photomask. The second sub-patterns are formed on the first layer using patterns at a second side of the first photomask, so that the first sub-patterns and the second sub-patterns are alternately arranged.

In an embodiment of the manufacturing method of the overlay mark of the present invention, the first sub-patterns are bar-shaped patterns.

In an embodiment of the manufacturing method of the overlay mark of the present invention, the second sub-patterns are bar-shaped patterns.

In an embodiment of the manufacturing method of the overlay mark of the present invention, the plurality of second patterns includes a plurality of third sub-patterns and a plurality of fourth sub-patterns arranged alternately.

In an embodiment of the manufacturing method of the overlay mark of the present invention, a forming method of the second stitching overlay mark structure includes the following steps. The third sub-patterns are formed on the second layer using patterns at a first side of a second photomask. The fourth sub-patterns are formed on the second layer using patterns at a second side of the second photomask, so that the third sub-patterns and the fourth sub-patterns are alternately arranged and the first sub-pattern, the third sub-pattern, the second sub-pattern and the fourth sub-pattern are alternately arranged in this order from the top view on the second layer.

In an embodiment of the manufacturing method of the overlay mark of the present invention, the third sub-patterns are bar-shaped patterns.

In an embodiment of the manufacturing method of the overlay mark of the present invention, the fourth sub-patterns are bar-shaped patterns.

The overlay measurement method using an overlay mark of the present invention includes the following steps. An overlay mark formed according to the above-mentioned manufacturing method is provided. A phase shift measurement is performed on the overlay mark. The phase shift measurement includes the following steps. A stitching overlay measurement step is performed on the plurality of first patterns or the plurality of second patterns to obtain a stitching overlay result. A layer-to-layer overlay measurement step is performed on the plurality of first patterns and the plurality of second patterns to obtain a layer-to-layer overlay result.

In an embodiment of the overlapping measurement method of the present invention, the plurality of first patterns includes a plurality of first sub-patterns and a plurality of second sub-patterns alternately arranged, and the plurality of second patterns includes a plurality of third sub-patterns and a plurality of fourth sub-patterns alternately arranged.

In an embodiment of the overlapping measurement method of the present invention, the stitching overlay measurement step is performed on the first sub-patterns and the second sub-patterns to obtain a first stitching overlay result.

In an embodiment of the overlapping measurement method of the present invention, the stitching overlay measurement step is performed on the third sub-patterns and the fourth sub-patterns to obtain a second stitching overlay result.

In an embodiment of the overlapping measurement method of the present invention, the layer-to-layer overlay measurement step is performed on the first sub-patterns and the third sub-patterns to obtain a first layer-to-layer overlay result.

In an embodiment of the overlapping measurement method of the present invention, the layer-to-layer overlay measurement step is performed on the first sub-patterns and the fourth sub-patterns to obtain a second layer-to-layer overlay result.

In an embodiment of the overlapping measurement method of the present invention, the layer-to-layer overlay measurement step is performed on the second sub-patterns and the third sub-patterns obtain a third layer-to-layer overlay result.

In an embodiment of the overlapping measurement method of the present invention, the layer-to-layer overlay measurement step is performed on the second sub-patterns and the fourth sub-patterns obtain a fourth layer-to-layer overlay result.

Based on the above, in the present invention, the overlay mark includes two stitching overlay mark structures formed in different layers respectively, and the two stitching overlay mark structures are formed in the different layers in a layer-to-layer overlay mark structure. In this way, the overlay mark of the present invention may have the characteristics of the stitching overlay mark structure and the layer-to-layer overlay mark structure at the same time. Therefore, when performing the overlay measurement, in addition to checking the stitching overlay alignment of the target pattern in each layer, a multi-check of the layer-to-layer overlay alignment between target patterns in different layers may also be performed.

### BRIEF DESCRIPTION OF THE DRAWINGS

FIGS. 1A to 1F are schematic top views of the manufacturing process of the overlay mark of the first embodiment of the present invention.

FIGS. 2A to 2F are schematic cross-sectional views of the manufacturing process according to the A-A section line in FIGS. 1A to 1F.

FIG. 3 is a schematic top view of the first photomask of the second embodiment of the present invention.

FIG. 4 is a schematic top view of the second photomask of the second embodiment of the present invention.

FIG. 5 is a schematic top view of the overlay mark of the second embodiment of the present invention.

FIG. 6 is a schematic top view of the photomask used to form the stitching overlay mark structure in other embodiments of the present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

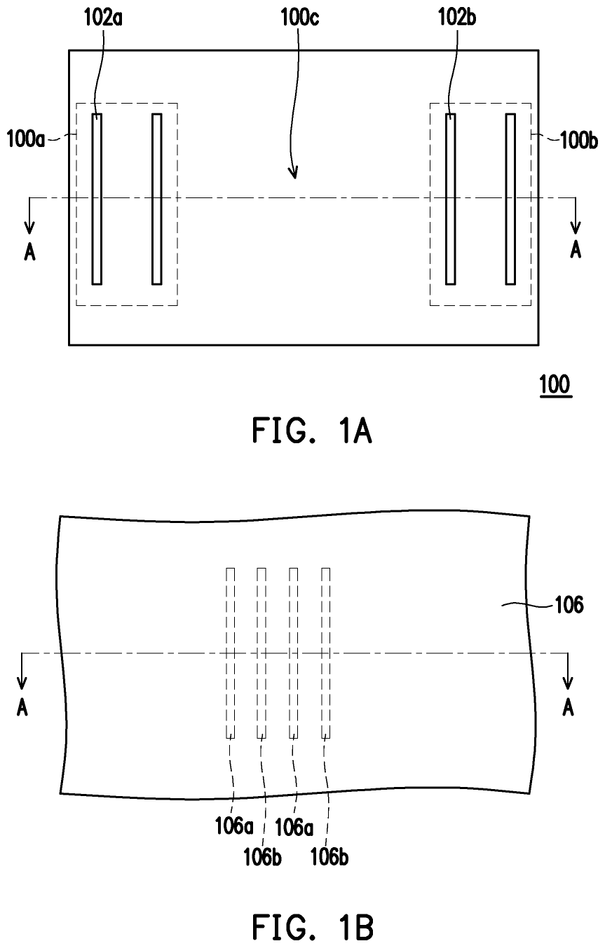

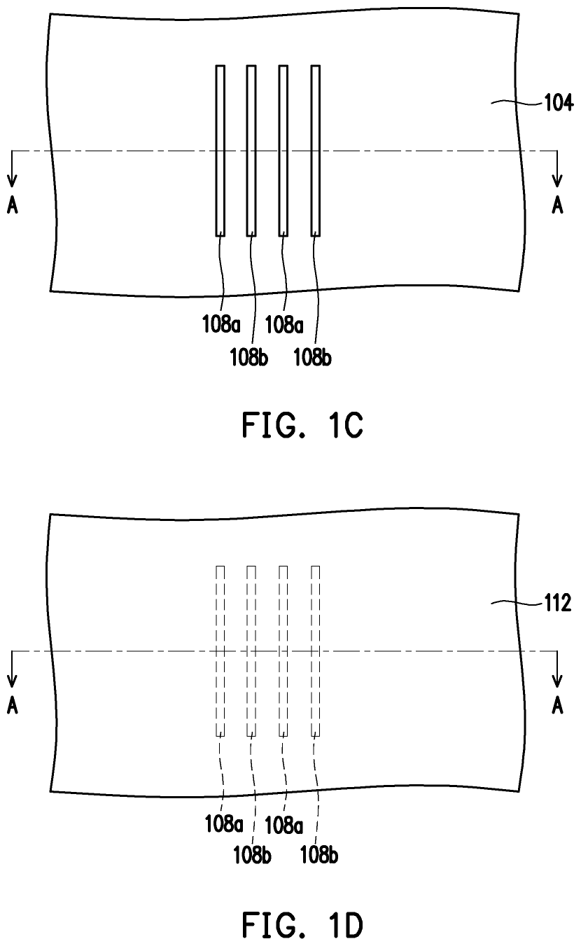

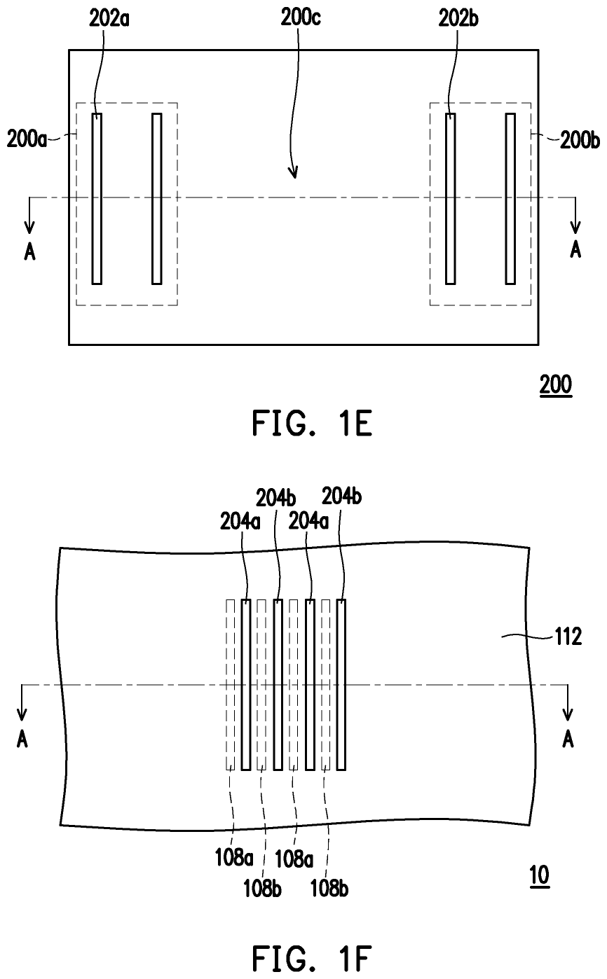

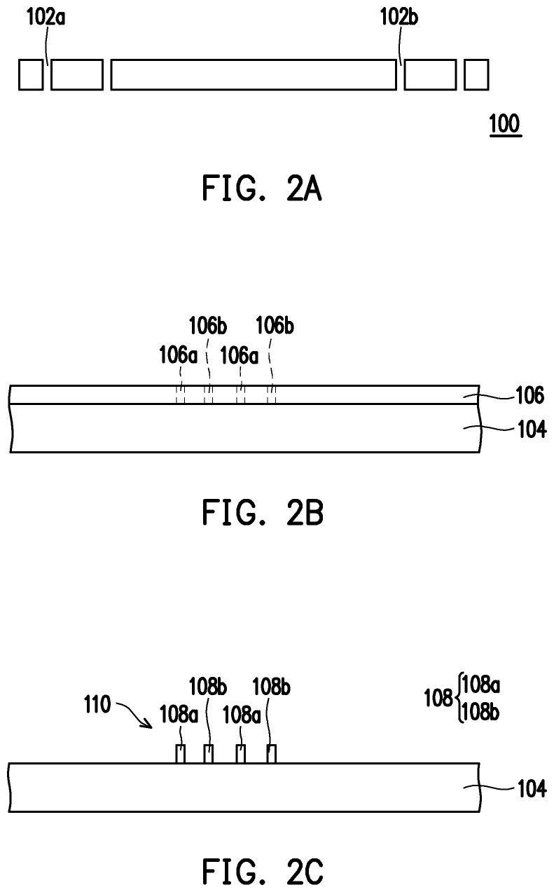

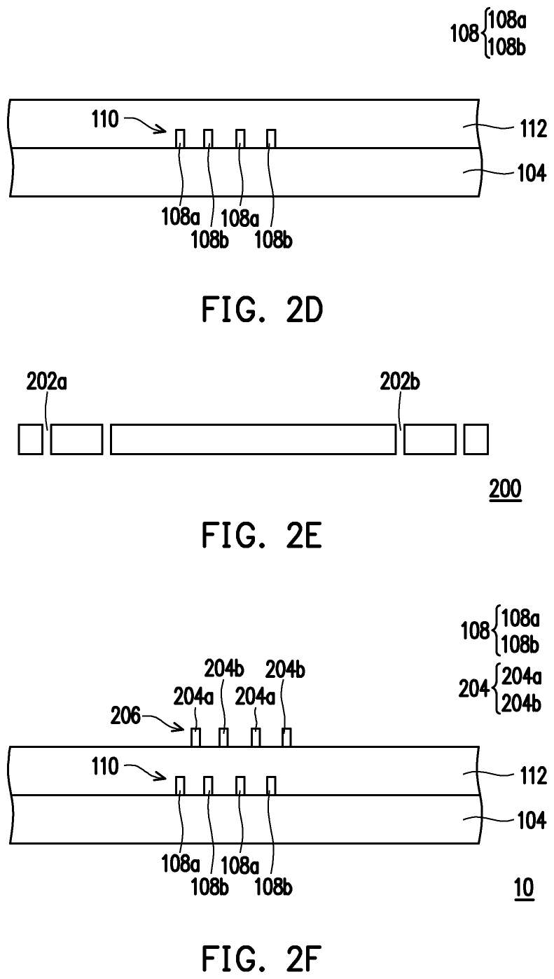

FIGS. 1A to 1F are schematic top views of the manufacturing process of the overlay mark of the first embodiment of the present invention. FIGS. 2A to 2F are schematic cross-sectional views of the manufacturing process according to the A-A section line in FIGS. 1A to 1F.

Referring to FIGS. 1A and 2A, a first photomask 100 is provided. In the present embodiment, the left region 100a of the first photomask 100 has a plurality of first opening patterns 102a arranged parallel to each other, and the right region 100b of the first photomask 100 has a plurality of second opening patterns 102b arranged parallel to each other. In FIGS. 1A and 2A, in order to make the drawings clear, only two first opening patterns 102a and two second opening patterns 102b are shown, but the present invention is not limited thereto. Depending on actual needs, the first photomask 100 may have more first opening patterns 102a and more second opening patterns 102b. In the present embodiment, the first opening patterns 102a and the second opening patterns 102b are bar-shaped patterns, but the present invention is not limited thereto. In addition, in a region other than the left region 100a and the right region 100b, other patterns (not shown) to be transferred onto the chip may be provided. Therefore, the region other than the left region 100a and the right region 100b may be referred to as a target pattern region 100c.

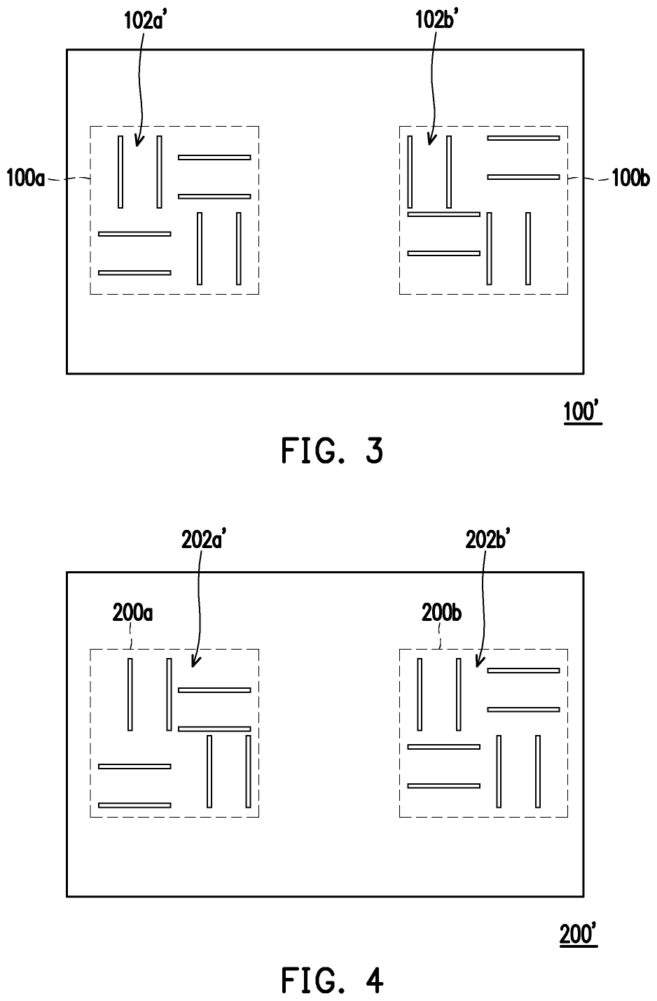

In the first photomask of other embodiments, the first opening patterns 102a and the second opening patterns 102b may have other types of pattern layout, and the present invention does not limit the layout of the opening patterns. For example, as shown in FIG. 3, in the first photomask 100′ of the second embodiment, there are first opening patterns 102a′ in the left region 100a and second opening patterns 102b′ in the right region 100b.

Referring to FIGS. 1B and 2B, a photoresist layer 106 is formed on a first layer 104. In the present embodiment, the first layer 104 may be a dielectric layer formed on a silicon substrate, but the present invention is not limited thereto. Then, a first exposure step is performed using the first opening patterns 102a located in the left region 100a of the first photomask 100 to form first exposure regions 106a corresponding to the first opening patterns 102a in the photoresist layer 106. Next, a second exposure step is performed using the second opening patterns 102b located in the right region 100a of the first photomask 100 to form second exposure regions 106b corresponding to the second opening patterns 102b in the photoresist layer 106, and the first exposure regions 106a and the second exposure regions 106b are alternately arranged.

Referring to FIGS. 1C and 2C, a developing step is performed on the photoresist layer 106 to form a plurality of first patterns 108 on the first layer 104. In the present embodiment, the first patterns 108 include bar-shaped first sub-patterns 108a corresponding to the first opening patterns 102a and bar-shaped second sub-patterns 108b corresponding to the second opening patterns 102b. In the present embodiment, the first sub-patterns 108a and the second sub-patterns 108b are alternately arranged on the first layer 104 to form a first stitching overlay mark structure 110.

Referring to FIGS. 1D and 2D, a second layer 112 is formed on the first layer 104. The second layer 112 covers the first stitching overlay mark structure 110 formed on the first layer 104. In the present embodiment, the second layer 112 may be a dielectric layer, but the present invention is not limited thereto.

Referring to FIGS. 1E and 2E, a second photomask 200 is provided. In the present embodiment, the left region 200a of the second photomask 200 has a plurality of third opening patterns 202a arranged parallel to each other, and the right region 200b of the second photomask 200 has a plurality of fourth opening patterns 202b arranged parallel to each other. The left region 200a of the second photomask 200 has the same pattern layout as the left region 100a of the first photomask 100, and the right region 200b of the second photomask 200 has the same pattern layout as the right region 100b of the first photomask 100. The third opening patterns 202a and the fourth opening patterns 202b are bar-shaped patterns. In addition, in a region other than the left region 200a and the right region 200b, other patterns (not shown) to be transferred onto the chip may be provided. Therefore, the region other than the left region 200a and the right region 200b may be referred to as a target pattern region 200c.

In other embodiments, in a case of using the first photomask 100′, the left region and right region of the second photomask have the same pattern layout as the left region and right region of the first photomask 100′. As shown in FIG. 4, in the second photomask 200′ of the second embodiment, the left region 200a has the same third opening patterns 202a′ as the first opening patterns 102a′, and the right region 200b has the same fourth opening patterns 202b′ as the second opening pattern 102b′.

Referring to FIGS. 1F and 2F, and the steps described in FIGS. 1B, 2B, 1C and 2C are performed, the exposure steps are performed using the third opening patterns 202a located in the left region 200a of the second photomask 200 and the fourth opening patterns 202b located in the right region 200b of the second photomask 200 respectively, so as to form a plurality of second patterns 204 on the second layer 112. In the present embodiment, the second patterns 204 include bar-shaped third sub-patterns 204a corresponding to the third opening patterns 202a and bar-shaped fourth sub-patterns 204b corresponding to the fourth opening patterns 202b. In the present embodiment, the third sub-patterns 204a and the fourth sub-patterns 204b are alternately arranged on the second layer 112 to form a second stitching overlay mark structure 206. In this way, a overlay mark 10 of the present embodiment is formed.

In the overlay mark 10, the second stitching overlay mark structure 206 is located above the first stitching overlay mark structure 110. In addition, from a top view on the second layer 112, the second patterns 204 and the first patterns 108 are arranged alternately. In detail, in the present embodiment, from the top view on the second layer 112, the first sub-pattern 108a, the third sub-pattern 204a, the second sub-pattern 108b and the fourth sub-pattern 204b are alternately arranged in this order.

In the present embodiment, the first patterns 108 constituting the first stitching overlay mark structure 110 and the second patterns 204 constituting the second stitching overlay mark structure 206 are photoresist patterns formed by the photoresist layers, but the present invention is not limited thereto. In other embodiments, the stitching overlay mark structure may be a material pattern formed by using the photoresist patterns as etching masks to perform etching processes on other material layers.

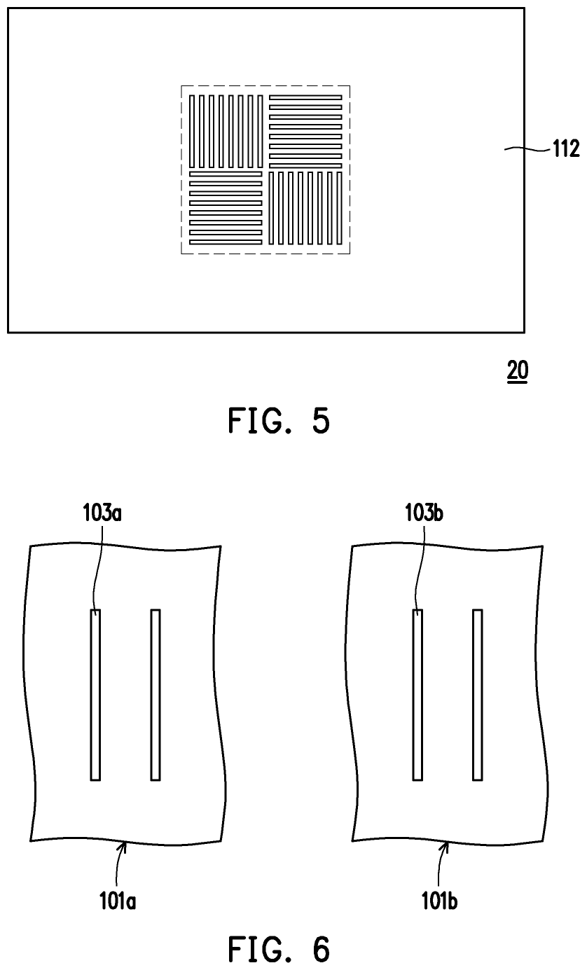

In addition, in a case of using the first photomask 100′ and the second photomask 200′, a formed overlay mark 20 may be as shown in FIG. 5.

In the present embodiment, the overlay mark 10 includes two stitching overlay mark structures respectively located in different levels, and the two stitching overlay mark structures are disposed in different levels in a layer-to-layer overlay mark structure manner. In this way, the overlay mark 10 may simultaneously have the characteristics of the stitching overlay mark structure and the layer-to-layer overlay mark structure. Therefore, when the overlay mark 10 is used for the overlay measurement, the overlay mark 10 may provide various overlay performances to facilitate the evaluation of the overlay accuracy. This will be described in detail below.

Referring to FIG. 1F, during the overlay measurement using the overlay mark 10, a phase shift measurement is performed on the overlay mark 10. The phase shift measurement may include the following six steps.
(1) a stitching overlay measurement step is performed on the first sub-patterns 108a and the second sub-patterns 108b to obtain a stitching overlay result related to forming the stitching target pattern on the first layer 104 using the first photomask 100.
(2) a stitching overlay measurement step is performed on the third sub-patterns 204a and the fourth sub-patterns 204b to obtain a stitching overlay result related to forming the stitching target pattern on the second layer 112 using the second photomask 200.
(3) a layer-to-layer overlay measurement step is performed on the first sub-patterns 108a and the third sub-patterns 204a to obtain a layer-to-layer overlay result related to the stitching target pattern formed on the first layer 104 and the stitching target pattern formed on the second layer 112.
(4) a layer-to-layer overlay measurement step is performed on the first sub-patterns 108a and the fourth sub-patterns 204b to obtain a layer-to-layer overlay result related to the stitching target pattern formed on the first layer 104 and the stitching target pattern formed on the second layer 112.
(5) a layer-to-layer overlay measurement step is performed on the second sub-patterns 108b and the third sub-patterns 204a to obtain a layer-to-layer overlay result related to the stitching target pattern formed on the first layer 104 and the stitching target pattern formed on the second layer 112.
(6) a layer-to-layer overlay measurement step is performed on the second sub-patterns 108b and the fourth sub-patterns 204b to obtain a layer-to-layer overlay result related to the stitching target pattern formed on the first layer 104 and the stitching target pattern formed on the second layer 112.

In the above phase shift measurement, the overlay mark 10 may be used for checking the stitching overlay alignment of the target pattern in each layer and for a multi-check of the layer-to-layer overlay alignment between target patterns in different layers. In addition, since the overlay mark 10 has the characteristics of the stitching overlay mark structure and the layer-to-layer overlay mark structure at the same time, the problem of the stitching overlay mark and the layer-to-layer overlay mark occupying too much layout area may be prevented.

In each of the above embodiments, a photomask is used to form the stitching overlay mark structure, but the present invention is not limited thereto. In other embodiments, at least two photomasks may also be used to form a stitching overlay mark structure.

For example, when forming the first stitching overlay mark structure 110, the photomask 101a and the photomask 101b may be used to replace the first photomask 100, as shown in FIG. 6. The photomask 101a has patterns 103a to correspond to the left region 100a of the first photomask 100, and the photomask 101b has patterns 103b to correspond to the right region 100b of the first photomask 100. The method of using the photomask 101a and the photomask 101b to form a stitching overlay mark structure is well known to those skilled in the art, and will not be repeated here.

Similarly, when forming the second stitching overlay mark structure 206, a photomask having patterns to correspond to the left region 200a of the second photomask 200 and a photomask having patterns to correspond to the right region 200b of the second photomask 200 may also be used to replace the second photomask 200.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A manufacturing method of an overlay mark, comprising:
forming a first stitching overlay mark structure having a plurality of first patterns on a first layer;
forming a second layer on the first layer; and
forming a second stitching overlay mark structure having a plurality of second patterns on the second layer,
wherein the second stitching overlay mark structure is located above the first stitching overlay mark structure, and from the top view on the second layer, the second patterns and the first patterns are alternately arranged.

2. The manufacturing method of claim 1, wherein the plurality of first patterns comprises a plurality of first sub-patterns and a plurality of second sub-patterns arranged alternately.

3. The manufacturing method of claim 2, wherein a forming method of the first stitching overlay mark structure comprises:
forming the first sub-patterns on the first layer using patterns at a first side of a first photomask; and
forming the second sub-patterns on the first layer using patterns at a second side of the first photomask, so that the first sub-patterns and the second sub-patterns are alternately arranged.

4. The manufacturing method of claim 2, wherein the first sub-patterns are bar-shaped patterns.

5. The manufacturing method of claim 2, wherein the second sub-patterns are bar-shaped patterns.

6. The manufacturing method of claim 1, wherein the plurality of second patterns comprises a plurality of third sub-patterns and a plurality of fourth sub-patterns arranged alternately.

7. The manufacturing method of claim 6, wherein a forming method of the second stitching overlay mark structure comprises:
forming the third sub-patterns on the second layer using patterns at a first side of a second photomask; and
forming the fourth sub-patterns on the second layer using patterns at a second side of the second photomask, so that the third sub-patterns and the fourth sub-patterns are alternately arranged and the first sub-pattern, the third sub-pattern, the second sub-pattern and the fourth sub-pattern are alternately arranged in this order from the top view on the second layer.

8. The manufacturing method of claim 6, wherein the third sub-patterns are bar-shaped patterns.

9. The manufacturing method of claim 6, wherein the fourth sub-patterns are bar-shaped patterns.

10. An overlay measurement method, using an overlay mark, comprising:
providing an overlay mark formed according to the manufacturing method of claim 1; and
performing a phase shift measurement on the overlay mark,
wherein the phase shift measurement comprises:
performing a stitching overlay measurement step on the plurality of first patterns or the plurality of second patterns to obtain a stitching overlay result; and
performing a layer-to-layer overlay measurement step on the plurality of first patterns and the plurality of second patterns to obtain a layer-to-layer overlay result.

11. The overlay measurement method of claim 10, wherein the plurality of first patterns comprises a plurality of first sub-patterns and a plurality of second sub-patterns alternately arranged, and the plurality of second patterns comprises a plurality of third sub-patterns and a plurality of fourth sub-patterns alternately arranged.

12. The overlay measurement method of claim 11, wherein the stitching overlay measurement step is performed on the first sub-patterns and the second sub-patterns to obtain a first stitching overlay result.

13. The overlay measurement method of claim 11, wherein the stitching overlay measurement step is performed on the third sub-patterns and the fourth sub-patterns to obtain a second stitching overlay result.

14. The overlay measurement method of claim 11, wherein the layer-to-layer overlay measurement step is performed on the first sub-patterns and the third sub-patterns to obtain a first layer-to-layer overlay result.

15. The overlay measurement method of claim 11, wherein the layer-to-layer overlay measurement step is performed on the first sub-patterns and the fourth sub-patterns to obtain a second layer-to-layer overlay result.

16. The overlay measurement method of claim 11, wherein the layer-to-layer overlay measurement step is performed on the second sub-patterns and the third sub-patterns obtain a third layer-to-layer overlay result.

17. The overlay measurement method of claim 11, wherein the layer-to-layer overlay measurement step is performed on the second sub-patterns and the fourth sub-patterns obtain a fourth layer-to-layer overlay result.
